(19) United States
(12) Patent Application Publication
(10) Pub. No.: US 2005/0268181 A1
(43) Pub. Date: Dec. 1, 2005

(54) Method and apparatus to provide adaptive transmission parameters for wireless networks

(76) Inventors: Ravi A. Murty, Portland, OR (US); Michael B. Andrews, Beaveton, OR (US); Emily H. Qi, Porland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/839,054

(22) Filed: May 4, 2004

(51) Int. Cl. H04L 5/12; H04J 15/00; H04L 1/00; H04J 1/16; H04J 3/14; G06F 11/00; H04L 12/26; G08C 15/00; G01R 31/08

(52) U.S. Cl. 714/704

(57) ABSTRACT

A method and apparatus that dynamically adjust transmission parameters based on channel conditions. Channel conditions include error rate due to packet collisions and an error rate due to noise. Transmission parameters include a fragmentation threshold, a transmit rate, and a transmission protection mechanism threshold.

### BACKGROUND

### DESCRIPTION OF THE RELATED ART

Interference in a wireless network caused by packet collisions and noise increases packet loss rate and reduces throughput of a client and the overall throughput of a network. Transmission parameters, including for example, data rates, fragmentation sizes, and transmission protection mechanisms affect throughput in wireless networks and can compensate for effects due to noise and packet collisions. The values of these parameters are typically selected statically based on an estimation of the channel and traffic conditions of an expected wireless environment. However, channel and traffic conditions are difficult to predict and change dynamically.

### BRIEF DESCRIPTION OF THE DRAWINGS

The present invention may be better understood, and its numerous features and advantages made apparent to those skilled in the art by referencing the accompanying drawings.

FIG. 1 illustrates a wireless communication system according to an embodiment of the present invention.

FIG. 2 illustrates a flow chart for the dynamic adjustment of transmission parameters according to an embodiment of the present invention.

The use of the same reference symbols in different drawings indicates similar or identical items.

### DESCRIPTION OF THE EMBODIMENT(S)

In the following description, numerous specific details are set forth. However, it is understood that embodiments of the invention may be practiced without these specific details. In other instances, well-known methods, structures and techniques have not been shown in detail in order not to obscure an understanding of this description.

References to “one embodiment,” “an embodiment,” “example embodiment,” “various embodiments,” etc., indicate that the embodiment(s) of the invention so described may include a particular feature, structure, or characteristic, but not every embodiment necessarily includes the particular feature, structure, or characteristic. Further, repeated use of the phrase “in one embodiment” does not necessarily refer to the same embodiment, although it may.

Unless specifically stated otherwise, as apparent from the following discussions, it is appreciated that throughout the specification discussions utilizing terms such as “processing,” “computing,” “calculating,” or the like, refer to the action and/or processes of a computer or computing system, or similar electronic computing device, that manipulate and/or transform data represented as physical, such as electronic, quantities into other data similarly represented as physical quantities.

In a similar manner, the term “processor” may refer to any device or portion of a device that processes electronic data from registers and/or memory to transform that electronic data into other electronic data that may be stored in registers and/or memory. A “computing platform” may comprise one or more processors.

As used in this application the following terms may have the following meanings: ‘transmission quality’ may mean the number of frames that are transmitted over a WLAN or other wireless network, relative to the number of such frames that are acknowledged, through for example an acknowledgment (ACK) response frame, as received by a peer. Transmission (Tx) quality may be expressed as a percentage, such as for example a Packet Error Rate (PER) percentage, which may be, for example, the number of frames for which an ACK acknowledgement frame has not been received, over the number of frames transmitted in a particular period. In some embodiments, a success/fail rate of transmitted frames may be measured or calculated over an interval of, for example, a most recent group of frames that were transmitted, such as for example, the last 100 or 1000 frames transmitted. In other embodiments, a success/fail rate or a PER may be calculated over a given time period. Other measures or periods of calculations may be used. A Tx quality threshold may be a level of Tx quality, below which, some corrective action or adjustment to transmission parameters may be appropriate.

The term ‘data rate’ may mean for example the rate at which bytes of data are sent over a wireless link or between wireless communication devices. Data rate may be expressed in mega bytes per second (Mbps), or through other units of expression. The term ‘fragmentation’ may mean for example breaking frames such as for example medium access control service data units (MSDU) into fragments such as for example medium access control protocol data units (MPDU) before transmission of the frame or data unit. Fragmentation may, in some embodiments, effect or improve the reliability or quality of transmissions since for example, smaller frames may have less chance of being interrupted by noise or collisions. The size of fragments may in some embodiments be set from for example, 256 bytes to 2048 bytes per fragment, and the size of fragments may in some embodiments be adjustable by a user or by a WLAN controller or other network controller. Other fragment sizes may be used and other triggers for implementing fragmentation may be used. In some system configurations, the fragmentation of frames may be controlled by a Transmission Scheduler (Tx Scheduler).

The term ‘request to send’ (RTS) may for example mean an optional feature of the IEEE Std. 802.11 published 1999, and more particularly to the IEEE-802.11a-1999, IEEE-Std. 802.11b-1999, and IEEE-Std 802.11g that instruct a station to refrain from sending a data frame until the station completes a RTS/clear-to-send (CTS) handshake with a peer such as for example an access point. Other systems and other standards may use protocols similar to the RTS/CTS functions. In some systems or standards, CTS may contain a time value that alerts other stations to hold off from accessing the wireless medium while the initiating RTS station transmits its data. In this way, RTS/CTS protection may minimize collisions among frames sent by stations on the same medium. Other implementations and functions of RTS/CTS operations are possible. In some configurations or transmissions, RTS protection may be added to some, all or none of transmitted packets. For example, the size of a packet may be a determining factor in whether RTS protection is added to a packet. For example, if an ‘RTS threshold’ of 1,000 bytes is implemented, then RTS protection may be applied to packets of 1,000 bytes or more. Transmitting without RTS protection or deactivating RTS protection may be implemented by setting the RTS threshold above the size of most or all of the packets to be transmitted. The term ‘data sampling threshold’ may mean for example a minimum number of frames that are transmitted and evaluated for success/fail rate or a minimum period of transmission that may be monitored in order to determine a Tx quality. For example, in some embodiments, a determination of Tx quality may be made on the basis of a PER of the last 100 frames or the last 100 milliseconds, if desired. In other embodiments, determination of Tx quality may be made on the basis of a PER of the last 1000 frames and/or the last 1000 milliseconds, if desired. Other limits or measures may be used as a scale or a criteria in designating data sampling thresholds.

The term ‘collision rate threshold’ may mean for example the success/fail rate of transmitted packets that is attributable to collisions. For example, a collision rate threshold may be set at 15%, to indicate that, no adjustments to request to send protection need be made to correct transmission failure rates where 15% or less of the total failures are attributable to collisions.

The terms ‘attributable’ or ‘due to’ may mean for example that a factor such as for example noise, is a factor, though not necessarily the sole or even primary factor that contributes to a condition, such as for example, a high PER. In some embodiments in order to be ‘attributable to’, it may be sufficient that a factor contributes to a subject condition to the extent that reducing the prevalence of the factor may on the whole improve the subject condition.

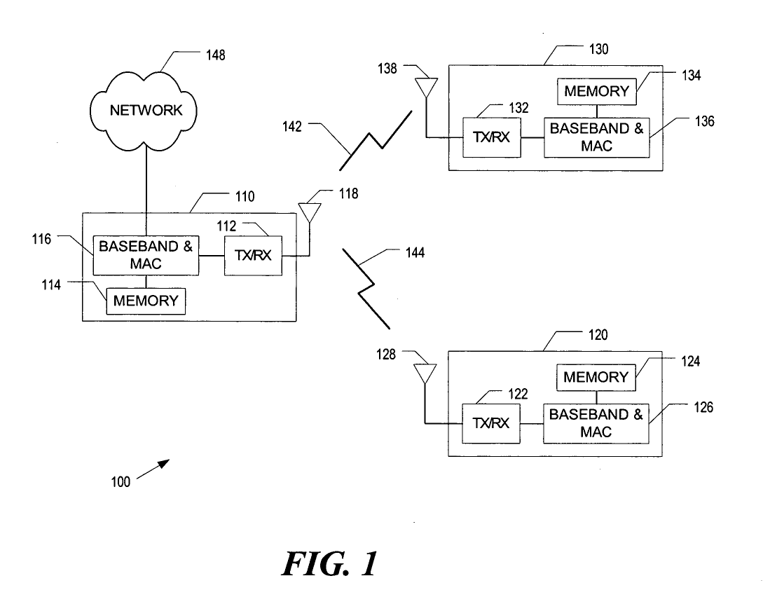

FIG. 1 illustrates a wireless communication system 100, for example, a wireless local area network (WLAN) communication system according to an embodiment of the present invention. Although the scope of the present invention is not limited in this respect, the exemplary WLAN communication system 100 may be defined, by IEEE 802.11-1999 standard, as a basic service set (BSS). For example, BSS may include at least one communication station, for example, an access point (AP) 110, and stations 120 and 130, at least one of which may be a mobile unit (MU). In some embodiments, stations 120 and 130 may transmit and/or receive one or more packets over wireless communication system 100. The packets may include data, control messages, network information, and the like. Additionally or alternatively, in other embodiments of the present invention, wireless communication system 100 may include two or more APs and two or more mobile stations. This arrangement of wireless communication system 100 may be referred by IEEE 802.11-1999 standard as extended service set (ESS), although the scope of the present invention is not limited in this respect.

Station 120 may include may include a wireless transceiver 122 to couple to an antenna 128 and to a baseband processor 126. Baseband processor 126 in one embodiment may include a single processor, or alternatively may include a baseband processor and an applications processor, although the scope of the invention is not limited in this respect. Baseband processor 126 may couple to a memory 124 which may include volatile memory such as DRAM, non-volatile memory such as flash memory, or alternatively may include other types of storage such as a hard disk drive, although the scope of the invention is not limited in this respect. Some portion or all of memory 124 may be included on the same integrated circuit as baseband processor 126, or alternatively some portion or all of memory 124 may be disposed on an integrated circuit or other medium, for example a hard disk drive, that is external to the integrated circuit of baseband processor 126, although the scope of the invention is not limited in this respect. Likewise, station 130 may include a transceiver 132, memory 134, baseband processor 136, and antenna 138. Access point 110 may include a transceiver 112, memory 114, baseband processor 116, and antenna 118.

Station 120 and station 130 may communicate with each other and with access point 110 via wireless communication links 142 and 144. Access point 110 may include at least one antenna 118. Alternatively, access point 110, and optionally station 120 and station 130, may include two or more antennas to provide a diversity antenna arrangement, to provide spatial division multiple access (SDMA), or to provide a multiple input, multiple output (MIMO) system, or the like, although the scope of the invention is not limited in this respect. Access point 110 may couple with network 148 so that station 120 and station 130 may communicate with network 148, including devices coupled to network 148, by communicating with access point 110 via wireless communication links 142 and 144. Network 148 may include a public network such as a telephone network or the Internet, or alternatively network 148 may include a private network such as an intranet, or a combination of a public and a private network, although the scope of the invention is not limited in this respect.

Communication between user station 120 and station 130 and access point 110 may be implemented in accordance with one or more wireless standards including, for example, one or more wireless cellular standards, one or more wireless networking standards, one or more radio frequency identification (RFID) standards, and/or others. In at least one implementation, for example, the communication is implemented in accordance with the Bluetooth short range wireless protocol (Specification of the Bluetooth System, Version 1.2, Bluetooth SIG, Inc., November 2003, and related specifications and protocols). Other possible wireless networking standards include, for example: IEEE 802.11 (ANSI/IEEE Std 802.11-1999 Edition and related standards), HIPERLAN 1, 2 and related standards developed by the European Telecommunications Standards Institute (ETSI) Broadband Radio Access Networks (BRAN), HomeRF (HomeRF Specification, Revision 2.01, The HomeRF Technical Committee, July, 2002 and related specifications), Ultrawideband, and/or others.

A media access control (MAC) layer manages and maintains communication in wireless communication system 100. The MAC layer coordinates access over a shared radio channel. The MAC layer may utilize different types of physical (PHY) layers (direct sequence, frequency hopping or infra red) and may use a carrier sensing scheme based on CSMA/CA (Carrier Sense Multiple Access/Collision Avoidance) to perform its functionality. A collision avoidance scheme with the use of acknowledgement packets (ACKs) may be used instead of a collision detection scheme.

Various transmission parameters may be defined at the MAC layer. According to one embodiment of the present invention, the environment of wireless communication system 100 is monitored and transmission parameters are adjusted dynamically in response to varying channel conditions to improve network throughput. When monitoring the channel conditions, cause of packet loss (and consequent increase in retransmissions) due to noise is distinguished from packet loss caused by collisions.

According to one embodiment of the present invention, three transmission parameters, in particular, a fragmentation threshold, a transmit rate, and a protection mechanism threshold are adjusted substantially simultaneously. A packet is divided into multiple sub-packets if a size of the packet exceeds the fragmentation threshold. Transmission data rate can be reduced to increase reliability of reception. A protection mechanism, for example based on the use of RTS and CTS frames, is used for packet transmission when a size of a packet exceeds the protection mechanism threshold.

Data packets (those received from higher layer protocols such as TCP/IP) and some large management frames may need to be broken into smaller pieces for transmission over the wireless medium. Fragmentation may improve performance by reducing the number of retransmissions when the channel is “noisy.” The packet loss rate goes up when the interference in the channel is large and causes packet corruption. The destination of the packet cannot recover from this packet corruption and fails to acknowledge the packet causing a retransmission after a timeout. In such situations making the packet smaller increases the chances of reliable packet transmissions and reduces the number of retransmissions per packet. The size of the “fragments” that are transmitted over the channel is decided by the value of the fragmentation threshold parameter. If the higher layer packet received is larger than this threshold, the packet is broken into multiple smaller fragments or sub-packets and each fragment is transmitted and acknowledged individually. If, for instance, the size of the packet received at the MAC layer is 1400 bytes and the value of this parameter is set to 500 bytes, the result is three MAC fragments of size 500, 500 and 400 bytes respectively. When the medium gets noisy, smaller fragments typically improve throughput. However, each fragment has its own MAC and PHY header and the overhead due to these headers may become significant when the size of the fragment becomes smaller, adversely affecting throughput.

The IEEE 802.11b standard-1999 supports four different transmission rates: 1, 2, 5.5 and 11 Mbps. Different transmission rates are supported by using different modulation schemes. For instance, 1 Mbps is based on Differential Binary Phase Shift Keying (DBPSK) and 2 Mbps uses Differential Quadrature Phase Shift Keying (DQPSK). To achieve higher transmission rates the 802.11b PHY layer uses Complementary Code Keying (CCK) modulation. To be able to maintain an acceptable bit-error rate (BER), a modulation scheme requires a certain level of signal-to-noise ratio (SNR). The SNR required to maintain the same BER increases as the transmit rate increases. Thus, when the signal strength relative to the noise strength (i.e. the SNR) decreases, for instance in a noisy environment, lowering the transmit rate may maintain acceptable levels of BER. Therefore, in some cases choosing a lower value for the transmit rate actually improves the throughput of the wireless medium.

Packet loss rate increases in highly congested environments due to packet collisions. In such situations the MAC layer may support a transmission protection mechanism, for example, the use of Request-to-Send and Clear-to-Send (RTS-CTS) frames before sending out data packets. The MAC layer uses these packets to reserve the medium thereby gaining exclusive access to the medium to ensure “collision free” packet transmission. The RTS-CTS packet exchange however is initiated only when the size of the higher layer packet is larger than the value of this parameter. Using a small value for this parameter may require RTS-CTS packet exchanges for most data frames, an overhead that reduces throughput.

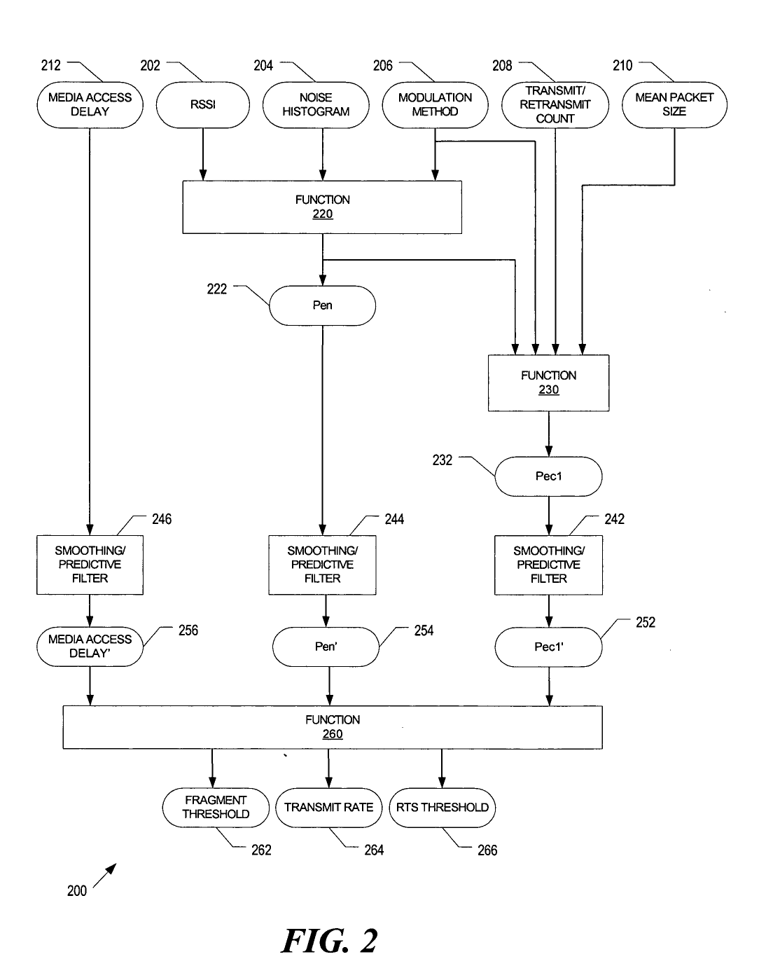

FIG. 2 illustrates a flow chart for the dynamic adjustment of transmission parameters according to an embodiment of the present invention. Flow 200 receives as inputs a received signal strength indicator (RSSI) 202, a noise histogram 204, a modulation method 206, a transmit/retransmit count 208, a mean packet size 210, and a media access delay 212.

RSSI 202 indicates the strength of the signal at the receiver. Noise histogram 204 provides an estimate of the noise strength at the receiver. A signal-to-noise-plus-interference ratio (SNIR) can be obtained by sampling RSSI 202 and the current noise level from noise histogram 204. The modulation method 206 is obtained from the current data rate. Transmit/retransmit count 208 indicates a count of the number of frames transmitted and retransmitted in the last sampling interval. Mean packet size 210 indicates the mean packet size of packets received from the layer above the MAC layer. Media access delay 212 represents the average amount of time a station had to wait to access the medium to transmit a fragment.

Function 220 computes the probability of noise induced bit error, Pₑₙ 222, based on current channel conditions as indicated by RSSI 202 and noise histogram 204. Function 220 also receives modulation method 206 because different modulation schemes use different encoding schemes.

The IEEE 802.11 standard—1999 defines a mechanism by which the RF energy is to be measured by the circuitry on a wireless network interface card (NIC). This numeric value is an integer with an allowable range of 0-255 (8-bit value) called the Received Signal Strength Indicator (RSSI). The RSSI value may be used to provide an indication of the signal strength at the receiver. Further, background RF energy (noise) and non-802.11 interference information may be obtained by requesting a noise histogram from another station, for example, AP 110. AP 110 responds with a noise histogram response frame containing relevant noise information. The histogram consists of received power indicator (RPI) densities. The RPI density may be defined as
└255*period−receiving−at−RPI/measurement−duration┘

The histogram densities provide an indication of the fraction of time the RPI was measured. To obtain a fair estimation of noise either a time weighted average or the mode of the histogram may be used. By looking at the densities of the noise histogram, the fraction of time each RPI was observed can be obtained as follows:
frac-time-rpi=(rpi_density/255)*total-measurement-duration
weighted-ave-noise=Σ(ave-rpi*frac-time-rpi)/total-duration-of-time
where ave_rpi is the average given an RPI index.

Alternatively, using the mode of the noise histogram provides an indication of how long a certain power was measured. This accounts for conditions where a device or interfering source may have been turned on and turned off causing a spike in the level of noise. Because a noise spike is a very short duration, using the mode will reduce the effects of the spike.

After obtaining an estimate of the receive signal strength and the noise power at the receiver, the probability of error Pₑₙ 222 may obtained by using a mathematical equation based on the modulation scheme (typically based on the current data rate). Listed below are equations to compute the probability of error for different modulation schemes supported by the IEEE 802.11b standard-1999. In the computation of Pₑₙ 222, the error function, ERFC, which is related to the Q function, is used. The Q function is defined as the area under the tail of the Gaussian probability density function with zero mean and unit variance.

$$Q ( x ) = 1 / √ ( 2 * Π ) {\int }_{x}^{∞} e - ( {t}^{2} / 2 ) ⅆ t$$

and ERFC is related to the Q function as follows:
Q(x)=½ERFC(x√2)

The modulation scheme for 1 Mbps uses differential binary phase shift keying (DBPSK). In this case Pₑₙ 222 is given by

$$\begin{matrix}{P}_{en} = Q ( √ ( 11 * SNR ) ) \\ = \frac{1}{2} ERFC ( √ ( 5.5 * SNR ) )\end{matrix}$$

The modulation scheme for 2 Mbps uses differential quadrature phase shift keying (DQPSK) chips. In this case Pₑₙ 222 is given by

$$\begin{matrix}{P}_{en} = Q ( √ ( 5.5 * SNR ) ) \\ = \frac{1}{2} ERFC ( √ ( 5.5 * SNR / 2 ) )\end{matrix}$$

For 5.5 Mbps, Pₑₙ 222 is given by

$$\begin{matrix}{P}_{en} = 8 / 15 ( 14 * Q ( √ ( 8 * SNR ) ) + Q ( √ ( 16 * SNR ) ) ) \\ = 8 / 15 ( 14 / 2 * ERFC ( √ ( 8 * SNR / 2 ) ) + \\ \frac{1}{2} ERFC ( √ ( 16 * SNR / 2 ) ) )\end{matrix}$$

For 11 Mbps, Pₑₙ 222 is given by

$$\begin{matrix}{P}_{en} = 24 * Q ( √ ( 4 * SNR ) ) + 16 * Q ( √ ( 6 * SNR ) ) + \\ 174 * Q ( √ ( 8 * SNR ) ) + 16 * Q ( √ ( 10 * SNR ) ) + \\ 24 * Q ( √ ( 12 * SNR ) ) + Q ( √ ( 16 * SNR ) ) \\ \\ = 24 * \frac{1}{2} * ERFC ( √ ( 4 * SNR ) ) + 16 * \frac{1}{2} * Q ( √ ( 6 * SNR ) ) + \\ 174 * \frac{1}{2} * Q ( √ ( 8 * SNR ) ) + 16 * \frac{1}{2} * Q ( √ ( 10 * SNR ) ) + \\ 24 * \frac{1}{2} * Q ( √ ( 12 * SNR ) ) + \frac{1}{2} * Q ( √ ( 16 * SNR ) )\end{matrix}$$

In one embodiment of the present invention, a lookup table based approach that maps the SNR to a bit-error rate is used, avoiding expensive computations at runtime.

The probability of packet error (Pₚₑᵣ) can be computed as follows:
Pₚₑᵣ=(1−(1−Pₑₙ)ⁿ) where n is the size of the packet.

Function 230 derives an estimate of the bit error rate due to packet collisions, normalized for a transmit rate of 1 Mbps. Using packet transmit and retransmit counts, an estimate of the total bit error rate Pₑ (the bit error rate resulting from both packet collisions and noise) is derived. The collision-induced bit error rate is then obtained by subtracting the noise-induced error rate from the total error rate. Finally, the collision-induced bit error rate, along with the current transmit rate, is used to estimate the “normalized” 1 Mbps collision-induced bit error rate (i.e., the error rate that is expected if the transmit rate were set to 1 Mbps).

The expected number of transmissions for a frame is given by,

$$E \{ TransmitCount \} = {\sum }_{i = 1}^{RetryCount} i * {P}_{f}^{i - 1} * {P}_{s} + ( RetryCount + 1 ) * {P}_{f}^{RetryCount}$$

Where Pₛ is the probability of successfully transmitting a packet or fragment in one attempt and is given by:
Pₛ=(1 Pₑ)^{8*PacketSize}

P_{f} is the probability of failing to successfully transmit a packet or fragment in one attempt and is given by:
P_{f}=1−Pₛ

Pₑ is the per-bit probability of error due to noise or packet collision and RetryCount is either set to long or short retry count and is based on the current value of the RTS Threshold.

From the above equations, the expected number of transmissions can be plotted against the probability of bit-error for different packet sizes and different retry counts. For a given packet size, retry count, and Pₑ range, a linear function which approximately maps Pₑ to E{TransmitCount} is given by:
E{TransmitCount}=a*Pₑ+b

By using the method of least squares, the values of a and b can be obtained. Because the output of function 230 is the probability of bit-error, the above equation can be rewritten as follows:

$${P}_{e} = α * E \{ TransmitCount \} + β$$

$$Where$$

$$α = \frac{1}{a} and β = - \frac{b}{a}$$

A set of values for alpha and beta for different packet sizes and both retry counts (short and long) can be derived. Pₑ from the current average transmit count can be obtained. Assuming all packet errors (and retransmits) are due to collisions or noise:
Pₑ=P_{ec}+Pₑₙ−P_{ec}*Pₑₙ

Where Pₑₙ is the estimated per-bit probability of error due to noise (the output of function block 1) and P_{ec} is the per-bit probability of error due to packet collision at the current transmit rate. Note that P_{ec}*Pₑₙ is subtracted from the sum of the individual probabilities to avoid double-counting the case where a packet experiences both a noise and a collision induced error. P_{ec}, can be estimated:

$${P}_{ec} = \frac{{P}_{e} - {P}_{en}}{1 - {P}_{en}}$$

Finally, given P_{ec} and the current transmit rate, the normalized collision-induced bit error rate P_{ec1} (the probability of collision-induced errors if the transmission were at 1 Mbps rather than the current transmit rate) can be calculated. If the current transmit rate is 1 Mbps, then P_{ec1}=P_{ec}.

Smoothing/predictive filters 242, 244, and 246 are used to predict trends in channel conditions, in particular, P_{ec1} 232, Pₑₙ 222, and media access delay 212, respectively. The filter outputs, P_{ec1}′ 252, Pₑₙ′ 254, and media access delay′ 256 are used by function 260 to estimate transmission parameters fragmentation threshold 262, transmit rate 264, and RTS threshold 266.

According to one embodiment of the present invention, function 260 calculates estimated theoretical throughput of a station with various combinations of fragmentation threshold 262, transmit rate 264, and RTS threshold 266 for the given probability of error due to collisions Pec1′ 252, probability of error due to noise Pen′ 254, and media access delay′ 256. The throughput can be computed by using a mathematical equation based on frame transmission probabilities. Throughput calculations are well known in the art and vary based on the particular wireless protocol and are therefore not shown here. The triplet providing the optimal throughput is selected. According to one embodiment of the present invention, function 260 utilizes a lookup table to provide the triplet that provides the best throughput for the client.

The techniques described above may be embodied in a computer-readable medium for configuring a computing system to execute the method. The computer readable media may be permanently, removably or remotely coupled to system 101, 201 or another system. The computer readable media may include, for example and without limitation, any number of the following: magnetic storage media including disk and tape storage media; optical storage media such as compact disk media (e.g., CD-ROM, CD-R, etc.) and digital video disk storage media; holographic memory; nonvolatile memory storage media including semiconductor-based memory units such as FLASH memory, EEPROM, EPROM, ROM; ferromagnetic digital memories; volatile storage media including registers, buffers or caches, main memory, RAM, etc.; and data transmission media including permanent and intermittent computer networks, point-to-point telecommunication equipment, carrier wave transmission media, the Internet, just to name a few. Other new and various types of computer-readable media may be used to store and/or transmit the software modules discussed herein. Computing systems may be found in many forms including but not limited to mainframes, minicomputers, servers, workstations, personal computers, notepads, personal digital assistants, various wireless devices and embedded systems, just to name a few. A typical computing system includes at least one processing unit, associated memory and a number of input/output (I/O) devices. A computing system processes information according to a program and produces resultant output information via I/O devices.

Realizations in accordance with the present invention have been described in the context of particular embodiments. These embodiments are meant to be illustrative and not limiting. Many variations, modifications, additions, and improvements are possible. Accordingly, plural instances may be provided for components described herein as a single instance. Boundaries between various components, operations and data stores are somewhat arbitrary, and particular operations are illustrated in the context of specific illustrative configurations. Other allocations of functionality are envisioned and may fall within the scope of claims that follow. Finally, structures and functionality presented as discrete components in the various configurations may be implemented as a combined structure or component. These and other variations, modifications, additions, and improvements may fall within the scope of the invention as defined in the claims that follow.

1. A method comprising:
adjusting a plurality of transmission parameters according to an error rate due to packet collisions and an error rate due to noise.

2. The method as recited in claim 1, wherein the plurality of transmission parameters comprise a fragmentation threshold, a data rate and a protection mechanism threshold.

3. The method as recited in claim 2, wherein a packet is divided into multiple sub-packets if a size of the packet exceeds the fragmentation threshold.

4. The method as recited in claim 2, wherein a protection mechanism is used for packet transmission when a size of a packet exceeds the protection mechanism threshold.

5. The method as recited in claim 1, further comprising:
determining the error rate due to noise from a received signal strength indicator and a current noise level.

6. The method as recited in claim 1, further comprising:
determining the error rate due to packet collisions by subtracting the error rate due to noise from a total error rate.

7. The method as recited in claim 1, wherein the adjusting the plurality of transmission parameters comprises:
for each of a plurality of transmission parameter groupings, estimating a throughput from the error rate due to noise, the error rate due to packet collisions, and a media access delay; and
selecting one of the plurality of transmission parameter groupings that provides a best throughput.

8. The method as recited in claim 1, wherein the adjusting the plurality of transmission parameters comprises:
using the error rate due to noise, the error rate due to packet collisions and a media access delay to select the plurality of transmission parameters from a lookup table.

9. A method comprising:
for each of a plurality of transmission parameter groupings, determining a throughput from an error rate due to noise, an error rate due to packet collisions, and a media access delay; and
selecting one of the plurality of transmission parameter groupings that provides a best throughput.

10. The method as recited in claim 9, wherein the plurality of transmission parameters comprise a fragmentation threshold, a data rate and a protection mechanism threshold.

11. The method as recited in claim 10, wherein a packet is divided into multiple sub-packets if a size of the packet exceeds the fragmentation threshold.

12. The method as recited in claim 10, wherein a protection mechanism is used for packet transmission when a size of a packet exceeds the protection mechanism threshold.

13. The method as recited in claim 9, further comprising:
determining the error rate due to noise from a received signal strength indicator and a current noise level.

14. The method as recited in claim 9, further comprising:
determining the error rate due to packet collisions by subtracting the error rate due to noise from a total error rate.

15. The method as recited in claim 9, wherein the determining the throughput comprises:
using the error rate due to noise, the error rate due to packet collisions and the media access delay to select the plurality of transmission parameters from a lookup table.

16. A method comprising dynamically adjusting transmission parameters based on an error rate due to collisions and an error rate due to noise.

17. The method as recited in claim 16, wherein the plurality of transmission parameters comprise a fragmentation threshold, a data rate and a protection mechanism threshold.

18. The method as recited in claim 17, wherein a packet is divided into multiple sub-packets if a size of the packet exceeds the fragmentation threshold.

19. The method as recited in claim 17, wherein a protection mechanism is used for packet transmission when a size of a packet exceeds the protection mechanism threshold.

20. The method as recited in claim 16, further comprising:
determining the error rate due to noise from a received signal strength indicator and a current noise level.

21. The method as recited in claim 16, further comprising:
determining the error rate due to packet collisions by subtracting the error rate due to noise from a total error rate.

22. The method as recited in claim 16, wherein the dynamically adjusting the plurality of transmission parameters comprises:
for each of a plurality of transmission parameter groupings, determining a throughput from the error rate due to noise, the error rate due to packet collisions, and a media access delay; and
selecting one of the plurality of transmission parameter groupings that provides a best throughput.

23. The method as recited in claim 16, wherein the dynamically adjusting the plurality of transmission parameters comprises:
using the error rate due to noise, the error rate due to packet collisions and a media access delay to select the plurality of transmission parameters from a lookup table.

24. An article comprising:
computer readable media; and
a set of instructions stored on the computer readable media, the instructions operable to:
determine a plurality of transmission parameters according to an error rate due to packet collisions and an error rate due to noise.

25. The article as recited in claim 24, wherein the plurality of transmission parameters comprise a fragmentation threshold, a data rate and a protection mechanism threshold.

26. The article as recited in claim 25, wherein a packet is divided into multiple sub-packets if a size of the packet exceeds the fragmentation threshold.

27. The article as recited in claim 25, wherein a protection mechanism is used for packet transmission when a size of a packet exceeds the protection mechanism threshold.

28. The article as recited in claim 24, the instructions further operable to:
determine the error rate due to noise from a received signal strength indicator and a current noise level.

29. The article as recited in claim 24, the instructions further operable to:
determine the error rate due to packet collisions by subtracting the error rate due to noise from a total error rate.

30. The article as recited in claim 24, wherein to determine the plurality of transmission parameters the instructions are operable to:
for each of a plurality of transmission parameter groupings, determine a throughput from the error rate due to noise, the error rate due to packet collisions, and a media access delay; and
select one of the plurality of transmission parameter groupings that provides a best throughput.

31. The article as recited in claim 24, wherein to determine the plurality of transmission parameters the instructions are operable to:
use the error rate due to noise, the error rate due to packet collisions and a media access delay to select the plurality of transmission parameters from a lookup table.

32. A communication device comprising:
a dipole antenna to transmit frames;
a throughput optimization unit to adjust a plurality of transmission parameters according to an error rate due to packet collisions and an error rate due to noise.

33. The communication device as recited in claim 32, wherein the plurality of transmission parameters comprise a fragmentation threshold, a data rate and a protection mechanism threshold.

34. The communication device as recited in claim 33, wherein a packet is divided into multiple sub-packets if a size of the packet exceeds the fragmentation threshold.

35. The communication device as recited in claim 33, wherein a protection mechanism is used for packet transmission when a size of a packet exceeds the protection mechanism threshold.

36. The communication device as recited in claim 32, further comprising:
an error rate calculation unit to determine the error rate due to noise from a received signal strength indicator and a current noise level.

37. The communication device as recited in claim 32, wherein the throughput optimization unit comprises:
a lookup table accessed by using the error rate due to noise, the error rate due to packet collisions and a media access delay to select the plurality of transmission parameters.
